(19) United States
(12) Patent Application Publication
(10) Pub. No.: US 2021/0048743 A1
(43) Pub. Date: Feb. 18, 2021

(54) Mask Plate, Manufacturing Method Thereof, and Patterning Method Using Mask Plate

(71) Applicants: Hefei Xinsheng Optoelectronics Technology Co., Ltd., Hefei (CN); BOE Technology Group Co., Ltd., Beijing (CN)

(72) Inventors: Li Yin, Beijing (CN); Qingpu Wang, Beijing (CN); Zhi Zhang, Beijing (CN); Zhenzhong Fang, Beijing (CN); Bisheng Li, Beijing (CN)

(73) Assignees: Hefei Xinsheng Optoelectronics Technology Co., Ltd., Hefei (CN); BOE Technology Group Co., Ltd., Beijing (CN)

(21) Appl. No.: 16/932,134

(22) Filed: Jul. 17, 2020

(30) Foreign Application Priority Data
Aug. 15, 2019 (CN) 201910754366.0

(51) Int. Cl. G03F 1/48; G06F 3/041

(52) U.S. Cl. CPC G03F 1/48; G06F 2203/04103; G06F 3/0412

(57) ABSTRACT

Disclosed are a mask plate, a manufacturing method thereof, and a patterning method using the mask plate. The mask plate includes: a first opening, configured to form a first protective layer for covering a first region, the first region including a functional region and a first wiring region at a periphery of the functional region; a second opening, connected to the first opening and configured to form a second protective layer for covering a second region, the second region includes a second wiring region; and a first shielding strip portion, the first protective layer and the second protective layer are connected and belong to a same film layer, the first shielding strip portion is configured to form a first groove region, the first groove region corresponds to a bonding region, and the second wiring region is on one side of the bonding region away from the first wiring region.

The present application claims priority of the Chinese Patent Application No. 201910754366.0 filed on Aug. 15, 2019. For all purposes under the U.S. law, the disclosure of the aforementioned application is incorporated by reference as part of the disclosure of the present application.

### TECHNICAL FIELD

Embodiments of the present disclosure relate to a mask plate, a manufacturing method thereof, and a patterning method using a mask plate.

### BACKGROUND

With the continuous development of display technology, touch technology has gradually been matured and the manufacturing techniques of touch technology has become stable. Therefore, touch technology has been widely used in various electronic products, such as notebook computer products.

OGM (One Glass Metal Mesh) touch technology integrates a metal mesh touch substrate on protective glass, so that a piece of protective glass plays a role of both protection and touch control. Therefore, OGM touch technology has the advantages of light weight, high light transmittance and low cost, etc.

### SUMMARY

The embodiments of the present disclosure provide a manufacturing method of a mask plate, a mask plate, and a patterning method using a mask plate. The mask plate includes: a first opening, configured to form a first protective layer for covering a first region of a plurality of functional substrates, the first region comprising a functional region and a first wiring region at a periphery of the functional region; a second opening, connected to the first opening and configured to form a second protective layer for covering a second region of at least one of the plurality of functional substrates, the second region comprising a second wiring region; and a first shielding strip portion, between the first opening and the second opening, wherein the first protective layer and the second protective layer are connected and belong to a same film layer, the first shielding strip portion is configured to form a first groove region of the film layer, the first groove region corresponds to a bonding region of the plurality of functional substrates, and the second wiring region is on one side of the bonding region away from the first wiring region.

For example, the mask plate provide by an embodiment of the present disclosure further includes: a third opening, communicated with the first opening, and oppositely arranged at an interval with the second opening; and a second shielding strip portion, between the first opening and the third opening, and configured to form a second groove region of the film layer.

For example, the mask plate provide by an embodiment of the present disclosure further includes: a fourth opening, configured to form a block pattern for covering a third region of the plurality of functional substrates, the third region comprising an alignment mark, wherein the block pattern and the first protective layer belong to the same film layer.

For example, in the mask plate provide by an embodiment of the present disclosure, each of the plurality of functional substrates comprises a base substrate and a plurality of wires, an orthographic projection of the plurality of wires on the base substrate falls within an orthographic projection of the first protective layer on the base substrate; a size of the first protective layer in each kind of N kinds of functional substrates in a first direction is Lᵢ, and a width of each of the plurality of wires in each kind of the N kinds of functional substrates is Wᵢ; a size X of the first opening in the first direction is greater than a size Lₘᵢₙ₁ of the first protective layer in a functional substrate with a minimum value of Wᵢ among the N kinds of functional substrates in the first direction, and the functional substrate further comprises a bonding region, the first direction is perpendicular to a direction from the functional region to the bonding region, N is a positive integer greater than or equal to 3, and i is a positive integer greater than or equal to 1 and less than or equal to N.

For example, in the mask plate provide by an embodiment of the present disclosure, an interval width between two adjacent wires is Sᵢ, and the size X of the first opening in the first direction is greater than a size Lₘᵢₙ₂ of the first protective layer in a functional substrate with a minimum value of Sᵢ among the N kinds of functional substrates in the first direction.

For example, in the mask plate provide by an embodiment of the present disclosure, the size X of the first opening in the first direction is greater than a median Lₘ of Lᵢ in the N kinds of functional substrates.

For example, in the mask plate provide by an embodiment of the present disclosure, a size of the first protective layer in each kind of the N kinds of functional substrates in a second direction is Dᵢ, a size Y of the first opening in the second direction is greater than a size Dₘᵢₙ₁ of the first protective layer in the functional substrate with the minimum value of Wᵢ among the N kinds of functional substrates in the second direction, and the second direction is perpendicular to the first direction.

For example, in the mask plate provide by an embodiment of the present disclosure, the interval width between two adjacent wires is Sᵢ, and the size Y of the first opening in the second direction is greater than a size Dₘᵢₙ₂ of the first protective layer in a functional substrate with a minimum value of Sᵢ among the N kinds of functional substrates in the second direction.

For example, in the mask plate provide by an embodiment of the present disclosure, the size Y of the first opening in the second direction is greater than a median Dₘ of Dᵢ in the N kinds of functional substrates.

At least one embodiment of the present disclosure further provides a patterning method using the mask plate described above, which includes: patterning an optical adhesive layer of N kinds of functional substrates using the mask plate.

For example, the patterning method using the mask plate provide by an embodiment of the present disclosure further includes: dividing a board into a plurality of sub-boards; taking a first center of the plurality of sub-boards as a benchmark, and aligning a second center of the first opening with the first center; and using the mask plate as a mask to perform an exposure process on the plurality of sub-boards.

At least one embodiment of the present disclosure further provides a manufacturing method of a mask plate, which includes: forming a first opening on the mask plate, wherein the first opening is configured to form a first protective layer for covering a first region of a plurality of functional substrates, and the first region comprises a functional region and a first wiring region at a periphery of the functional region; and forming a second opening on the mask plate, wherein the second opening is connected to the first opening and is configured to form a second protective layer for covering a second region of at least one of the plurality of functional substrates, and the second region comprises a second wiring region, wherein the mask plate comprises a first shielding strip portion between the first opening and the second opening, the first protective layer and the second protective layer are connected and belong to a same film layer, the first shielding strip portion is configured to form a first groove region of the film layer, the first groove region corresponds to a bonding region of the plurality of functional substrates, and the second wiring region is on one side of the bonding region away from the first wiring region.

For example, the manufacturing method of the mask plate provide by an embodiment of the present disclosure further includes: forming a third opening on the mask plate, wherein the third opening is communicated with the first opening and is oppositely arranged at an interval with the second opening, and the mask plate comprises a second shielding strip portion between the first opening and the third opening and configured to form a second groove region of the film layer.

For example, the manufacturing method of the mask plate provide by an embodiment of the present disclosure further includes: forming a fourth opening on the mask plate, wherein the fourth opening is configured to form a block pattern for covering a third region of the plurality of functional substrates, the third region comprises an alignment mark, and the block pattern and the first protective layer belong to the same film layer.

For example, in the manufacturing method of the mask plate provide by an embodiment of the present disclosure, each of the plurality of functional substrates comprises a base substrate and a plurality of wires, an orthographic projection of the plurality of wires on the base substrate falls within an orthographic projection of the first protective layer on the base substrate, and the forming the first opening on the mask plate comprises: determining a size Lᵢ of the first protective layer in each kind of N kinds of functional substrates in a first direction; determining a width Wᵢ of each of the plurality of wires in each kind of the N kinds of functional substrates; and determining a size X of the first opening in the first direction according to a size Lₘᵢₙ₁ of the first protective layer in a functional substrate with a minimum value of Wᵢ among the N kinds of functional substrates in the first direction, wherein the functional substrate further comprises a bonding region, the first direction is perpendicular to a direction from the functional region to the bonding region, N is a positive integer greater than or equal to 3, and i is a positive integer greater than or equal to 1 and less than or equal to N.

For example, in the manufacturing method of the mask plate provide by an embodiment of the present disclosure, an interval width between two adjacent wires is Sᵢ, and the forming the first opening on the mask plate further comprises: determining the size X of the first opening in the first direction according to a size Lₘᵢₙ₂ of the first protective layer in a functional substrate with a minimum value of Sᵢ among the N kinds of functional substrates in the first direction, where X is greater than Lₘᵢₙ₂.

For example, in the manufacturing method of the mask plate provide by an embodiment of the present disclosure, the forming the first opening on the mask plate further comprises: determining the size X of the first opening in the first direction according to a median Lₘ of Lᵢ in the N kinds of functional substrates, where X is greater than Lₘ.

For example, in the manufacturing method of the mask plate provide by an embodiment of the present disclosure, the forming the first opening on the mask plate further comprises: determining a size Dᵢ of the first protective layer in each kind of the N kinds of functional substrates in a second direction; and determining a size Y of the first opening in the second direction according to a size Dₘᵢₙ₁ of the first protective layer in the functional substrate with the minimum value of Wᵢ among the N kinds of functional substrates in the second direction, wherein the second direction is perpendicular to the first direction, and Y is greater than Dₘᵢₙ₁.

For example, in the manufacturing method of the mask plate provide by an embodiment of the present disclosure, the interval width between two adjacent wires is Sᵢ, and the forming the first opening on the mask plate further comprises: determining the size Y of the first opening in the second direction according to a size Dₘᵢₙ₂ of the first protective layer in a functional substrate with a minimum value of Sᵢ among the N kinds of functional substrates in the second direction, where Y is greater than Dₘᵢₙ₂.

For example, in the manufacturing method of the mask plate provide by an embodiment of the present disclosure, the forming the first opening on the mask plate further comprises: determining the size Y of the first opening in the second direction according to a median Dₘ of Dᵢ in the N kinds of functional substrates, where Y is greater than Dₘ.

### BRIEF DESCRIPTION OF THE DRAWINGS

In order to clearly illustrate the technical solutions of the embodiments of the disclosure, the drawings of the embodiments will be briefly described in the following; it is obvious that the described drawings are only related to some embodiments of the disclosure and thus are not limitative to the disclosure.

FIG. 1 is a flow chart of a manufacturing method of a mask plate according to an embodiment of the present disclosure;

FIG. 2 is a schematic plan view of a functional substrate according to an embodiment of the present disclosure.

FIG. 3 is a schematic plan view of another functional substrate according to an embodiment of the present disclosure;

FIG. 4 is a schematic plan view of a mask plate according to an embodiment of the present disclosure;

FIG. 5 is a schematic diagram of a patterning method using a mask plate according to an embodiment of the present disclosure;

FIG. 6 is a schematic diagram of a board divided into 30 sub-boards according to an embodiment of the present disclosure; and

FIG. 7 is a schematic diagram of a board divided into 32 sub-boards according to an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

In research, the inventors of the present application have found that the opening cost of notebook computer products using OGM touch technology is always high, and the main part of the opening cost is mask cost. At present, notebook computer products using OGM touch technology mainly use 4 mask plates and 6 mask processes. The four mask plates include a first mask plate for forming a black matrix (BM), a second mask plate for forming a first metal layer (Metal1), a third mask plate for forming a second metal layer (Metal2), and a fourth mask plate for forming an optical adhesive layer (OC); the 6 mask processes can include a mask process of forming a first optical adhesive layer on a base substrate by using the fourth mask plate, a mask process of forming the first metal layer on a side of the first optical adhesive layer away from the base substrate by using the first mask plate, a mask process of forming a second optical adhesive layer on a side of the first metal layer away from the first optical adhesive layer by using the fourth mask plate, a mask process of forming the second metal layer on a side of the second optical adhesive layer away from the first metal layer by using the third mask plate, and a mask process of forming a third optical adhesive layer on a side of the second metal layer away from the second optical adhesive layer by using the fourth mask plate. Because each time opening a new product, the 4 mask plates described above need to be redesigned, thus resulting in high opening cost.

The inventors of the present application hold that products of different styles with the same size and specification (e.g., 13.3 inches, 14 inches, 15.6 inches, etc.) can share the same mask plate to reduce the opening cost of notebook computer products using OGM touch technology. However, because the black matrix, the first metal layer and the second metal layer are limited by the pattern design of the products of different styles, the first mask plate, the second mask plate and the third mask plate cannot be shared on different products, so the inventors of the present application intends to design the fourth mask plate (that is, the mask plate for forming the optical adhesive layer,) suitable for different styles, thereby reducing the opening cost.

The embodiments of the disclosure provide a method of manufacturing a mask plate, a mask plate and a patterning method using a mask plate. The manufacturing method of the mask plate includes: forming a first opening on the mask plate, wherein the first opening is configured to pattern an optical adhesive layer of a functional substrate to form a first protective layer, and the first protective layer covers a functional region of the functional substrate. The functional substrate further includes a base substrate and a plurality of wires. The forming the first opening on the mask plate includes: determining a size Lᵢ of the first protective layer in each kind of N kinds of functional substrates in a first direction; determining a width Wᵢ of each of the plurality of wires in each kind of the N kinds of functional substrates; and determining a size X of the first opening in the first direction according to a size Lₘᵢₙ₁ of the first protective layer in a functional substrate with a minimum value of Wᵢ among the N kinds of functional substrates in the first direction, where X is greater than Lₘᵢₙ₁. The functional substrate further includes a bonding region, the first direction is perpendicular to a direction from the functional region to the bonding region, N is a positive integer greater than or equal to 3, and i is a positive integer greater than or equal to 1 and less than or equal to N. Therefore, the mask plate manufactured by the manufacturing method of the mask plate can be used for products of different styles with the same size and specification, thereby reducing the opening cost of electronic products such as notebook computer products.

Hereinafter, the manufacturing method of the mask plate, the mask plate and the patterning method using the mask plate provided by the embodiments of the present disclosure will be described in detail with reference to the accompanying drawings.

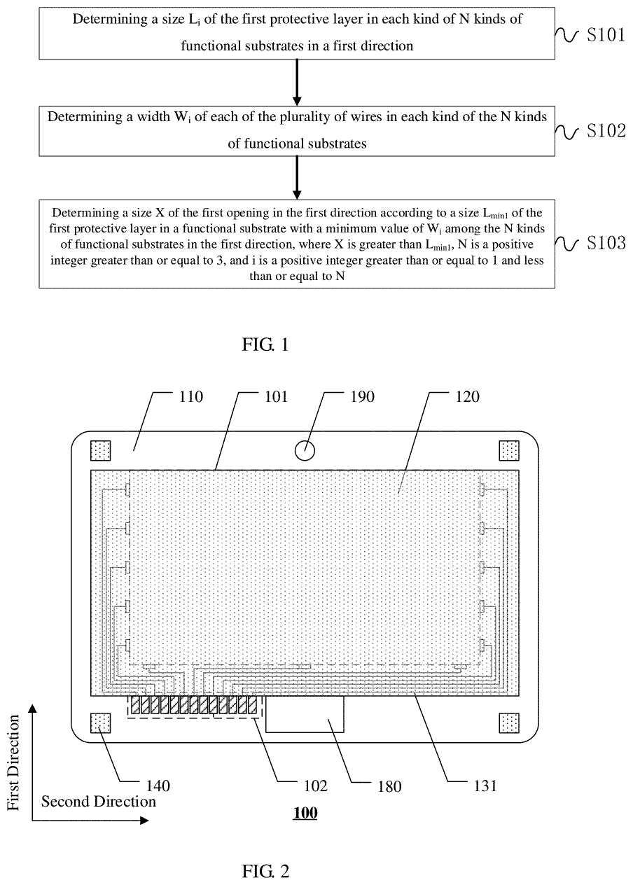

An embodiment of the present disclosure provides a manufacturing method of a mask plate. FIG. 1 is a flow chart of a manufacturing method of a mask plate according to an embodiment of the present disclosure, FIG. 2 is a schematic plan view of a functional substrate according to an embodiment of the present disclosure, and Table 1 is a statistical table showing the sizes of the first protective layers of N kinds of functional substrates in the first direction provided by an embodiment of the present disclosure.

As shown in FIG. 1, the manufacturing method of the mask plate includes: forming a first opening on the mask plate, wherein the first opening is configured to pattern an optical adhesive layer of a functional substrate to form a first protective layer, and the first protective layer covers at least a functional region of the functional substrate. For example, as shown in FIG. 2, the functional substrate 100 includes a first protective layer 120, the first protective layer covers a functional region 101 of the functional substrate 100, and the functional substrate can be an OGM (One Glass Metal Mesh) functional substrate. For example, as shown in FIG. 2, each kind of the N kinds of functional substrates further includes a base substrate 110 and a plurality of wires 131. An orthographic projection of the plurality of wires 131 on the substrate 110 falls within an orthographic projection of the first protective layer 120 on the substrate 110. For example, the wires 131 can be touch sensing lines and touch driving lines. For example, the touch sensing lines and the touch driving lines are wires located at an outer side of the functional region. For example, the functional substrate can be a touch substrate, and the functional region can be an effective touch region. The forming the first opening on the mask plate described above includes the following steps S101 to S103.

Step S101: determining a size Lᵢ of the first protective layer in each kind of N kinds of functional substrates in a first direction.

TABLE 1
Statistical Table of Sizes of First Protective Layers of
N Kinds of Functional Substrates in First Direction

| | | Distance | | | | |
|---|---|---|---|---|---|---|
| | | between | Distance | Wire width | Size of Region | |
| | Size of | Functional | between | and Interval | Needed to Be | Size of |
| | Functional | Region and | Functional | Width | Covered by | First |
| | Region in | Outer Edge of | Region and | between | First Protective | Opening in |
| 15.6 | First | Upper Ground | Bonding | Adjacent | Layer in First | First |
| inches | Direction | Wire | Region | Wires | Direction | Direction |
| 1 | 194.32 | 2.6451 | 6.15 | 17/17 | 203.1151 | 203 |
| 2 | 194.29 | 2.2501 | 4.54 | 15/15 | 201.0801 | 203 |
| 3 | 194.79 | 2.0494 | 5.83 | 15/15 | 202.6694 | 203 |
| 4 | 194.99 | 1.6348 | 4.76 | 15/15 | 201.3848 | 203 |
| 5 | 194.29 | 1.9948 | 4.76 | 15/15 | 201.0448 | 203 |
| 6 | 194.69 | 2.09 | 5.19 | 15/15 | 201.97 | 203 |
| 7 | 194.22 | 2.2319 | 8.54 | 30/30 | 204.9919 | 203 |
| 8 | 194.59 | 2.2949 | 8.11 | 30/30, 20/20 | 204.9949 | 203 |
| 9 | 194.22 | 2.6849 | 8.90 | 30/30 | 205.8049 | 203 |

For example, as shown in Table 1, the size of a region needed to be covered by the first protective layer in the first direction is equal to the sum of the size of the functional region in the first direction, the distance between the functional region and an outer edge of an upper ground line and the distance between the functional region and a bonding region.

For example, the functional substrate 100 further includes a bonding region 102, the first direction is perpendicular to the direction from the functional region 101 to the bonding region 102, N is a positive integer greater than or equal to 3, and i is a positive integer greater than or equal to 1 and less than or equal to N. For example, as shown in Table 1, taking 9 kinds of functional substrates of notebook computers with a size and specification of 15.6 inches as an example, the first protective layers of the 9 kinds of functional substrates have sizes Lᵢ, in the first direction, of 203.1151 mm, 201.0801 mm, 202.6694 mm, 201.3848 mm, 201.0448 mm, 201.97 mm, 204.9919 mm, 204.9949 mm and 205.8049 mm, respectively.

Step S102: determining a width Wᵢ of each of the plurality of wires in each kind of the N kinds of functional substrates.

For example, as shown in Table 1, taking 9 kinds of functional substrates of notebook computers with a size and specification of 15.6 inches as an example. The widths Wᵢ of wires of the 9 kinds of functional substrates are 17 microns, 15 microns, 15 microns, 15 microns, 15 microns, 15 microns, 30 microns, 30/20 microns and 30 microns, respectively.

Step S103: determining a size X of the first opening in the first direction according to a size Lₘᵢₙ₁ of the first protective layer in a functional substrate with a minimum value of Wᵢ among the N kinds of functional substrates in the first direction, where X is greater than Lₘᵢₙ₁. It should be noted that if the size of the first protective layer needed to be formed in a functional substrate with a relatively large value of Wᵢ among the N kinds of functional substrates is greater than the size of the first opening, the size of the first protective layer can be reduced by reducing the width of the wire, so that the mask plate provided by the present embodiment can meet the requirements of the N kinds of functional substrates. In addition, the above N kinds of functional substrates belong to functional substrates with the same size and specification.

For example, as shown in Table 1, taking 9 kinds of functional substrates of notebook computers with a size and specification of 15.6 inches as an example, the minimum value of Wᵢ in the 9 kinds of functional substrates is 15 microns, while the size Lₘᵢₙ₁ of the first protective layer of the functional substrate with the minimum value of Wᵢ in the 9 kinds of functional substrates in the first direction is 201.0801 mm, 202.6694 mm, 201.3848 mm, 201.0448 mm, 201.97 mm, respectively. And the size X of the first opening in the first direction is greater than L 1, so X can be 203 mm. That is, the size of the first opening of the mask plate shared by the 9 kinds of functional substrates in the first direction can be 203 mm. For example, the size of the first protective layer in the ninth functional substrate in the first direction is 205.8049 mm, and the corresponding wire width is 30 microns. The maximum number of parallel wires in the functional substrate of 15.6 inches in the first direction is usually 48+84=132. If the wire width is reduced from 30 microns to 15 microns, the size of the first protective layer of the functional substrate in the first direction can be reduced to 205.8049−132*0.030 (while the wire width is reduced, the interval width between wires can also be correspondingly reduced, so it is 0.015 times 2)=201.8449, which is less than the size X of the first opening in the first direction. The maximum size of the first protective layer in the first functional substrate in the first direction is 203.1151 mm, and the corresponding wire width is 17 microns. The maximum number of parallel wires in the functional substrate of 15.6 inches in the first direction is usually 48+84=132. If the wire width is reduced from 17 microns to 15 microns, the size of the first protective layer of the functional substrate in the first direction can be reduced to 203.1151−132*0.004=202.5871, which is less than the size X of the first opening in the first direction. Therefore, the mask plate manufactured by the manufacturing method of the mask plate can meet the requirements of the 9 kinds of functional substrates.

In the manufacturing method of the mask plate provided by the embodiment of the disclosure, the mask plate manufactured by the manufacturing method of the mask plate can be used for products of different styles, so that the mask plate for forming the first protective layer does not need to be redesigned each time opening a new product, and the opening cost can be effectively reduced.

In some examples, the interval width between two adjacent wires is Sᵢ, and the forming the first opening on the mask plate further includes: determining the size X of the first opening in the first direction according to a size Lₘᵢₙ₂ of the first protective layer in a functional substrate with a minimum value of Sᵢ among the N kinds of functional substrates in the first direction, where X is greater than Lₘᵢₙ₂.

For example, as shown in Table 1, taking 9 kinds of functional substrates of notebook computers with a size and specification of 15.6 inches as an example, the minimum value of Sᵢ in the 9 kinds of functional substrates is 15 microns, while the size Lₘᵢₙ₂ of the first protective layer of the functional substrate with the minimum value of Sᵢ in the 9 kinds of functional substrates in the first direction is 201.0801 mm, 202.6694 mm, 201.3848 mm, 201.0448 mm, 201.97 mm, respectively. And the size X of the first opening in the first direction is greater than Lₘᵢₙ₂, so X can be 203 mm. That is, the size of the first opening of the mask plate shared by the 9 kinds of functional substrates in the first direction can be 203 mm. For example, the size of the first protective layer in the ninth functional substrate in the first direction is 205.8049 mm, while the corresponding interval width between adjacent wires is 30 microns. The maximum number of parallel wires in the functional substrate of 15.6 inches in the first direction is usually 48+84=132. If the wire width is reduced from 30 microns to 15 microns and the interval width between adjacent wires is also reduced to 15 microns, the size of the first protective layer of the functional substrate in the first direction can be reduced to 205.8049−132*0.030=201.8449, which is less than the size X of the first opening in the first direction. The maximum size of the first protective layer in the first functional substrate in the first direction is 203.1151 mm, and the corresponding interval width between two adjacent wires is 17 microns. The maximum number of parallel wires in the functional substrate of 15.6 inches in the first direction is usually 48+84=132. If the sire width is reduced from 17 microns to 15 microns and the interval width between adjacent wires is also reduced to 15 microns, the size of the first protective layer of the functional substrate in the first direction can be reduced to 203.1151−132*0.004=202.5871, which is less than the size X of the first opening in the first direction. Therefore, the mask plate manufactured by the manufacturing method of the mask plate can meet the requirements of the 9 kinds of functional substrates.

In some examples, the forming the first opening on the mask plate further includes: determining the size X of the first opening in the first direction according to a median Lₘ of Lᵢ in the N kinds of functional substrates, where X is greater than Lₘ. Therefore, it can be ensured that the size X of the first opening in the first direction is at least greater than the size of the first protective layer of N/2 kinds of functional substrates in the first direction, so that on the one hand, the mask plate manufactured by the manufacturing method of the mask plate can meet the requirements of the N kinds of functional substrates, and on the other hand, the change in the wire width or the interval width between two adjacent wires with respect to the N kinds of functional substrates can be reduced.

In some examples, as shown in FIG. 2, the wires 131 includes touch driving lines (TX) and touch sensing lines (RX). For example, the functional substrate 100 further includes a bonding region 102, and the touch sensing lines can extend from the effective touch region 101 to the bonding region 102 along the first direction, and can be bonded to a corresponding receiving circuit in the bonding region 102. The touch driving lines extend from both sides of the functional region 101 to the bonding region 102, respectively, and are bonded to a corresponding driving circuit in the bonding region 102. Therefore, the maximum number of the wires arranged in parallel along the first direction between the functional region and the bonding region is usually the number of touch sensing lines plus half of the number of touch driving lines. It should be noted that the positions of the touch driving lines and the touch sensing lines can be interchanged.

In some examples, as shown in FIG. 2, the forming the first opening on the mask plate further includes: determining a size Dᵢ of the first protective layer in each kind of the N kinds of functional substrates in a second direction; determining a width Wᵢ of each of the plurality of wires in each kind of the N kinds of functional substrates; and determining a size Y of the first opening in the second direction according to a size Dₘᵢₙ₁ of the first protective layer in the functional substrate with the minimum value of Wᵢ among the N kinds of functional substrates in the second direction, wherein the wires extend along the first direction, and Y is greater than Dₘᵢₙ₁.

TABLE 2
Statistical Table of Sizes of First Protective Layers of
N Kinds of Functional Substrates in Second Direction

| | | Size of | | | |
|---|---|---|---|---|---|
| | | Region | | | |
| | | Needed | | | |
| | | to Be | | | |
| | | Covered by | | | Size of |
| | | First | | | First |
| | | Protective | | | Opening |
| | | Layer in | | | in |
| 15.6 | | Second | Winding Manner of | Port | Second |
| inches | Outline | Direction | Wires | Number | Direction |
| 1 | 352.94 | 351.32 | 30/30→20/20→15/15 | 48/84 | 352.3 |
| 2 | 355.2 | 352.68 | 30/30→20/20 | 48/84 | 352.3 |
| 3 | 353.5 | 351.285 | 30/30→20/20→15/15 | 48/84 | 352.3 |
| 4 | 355.1 | 351.305 | 30/30→20/20→15/15 | 48/84 | 352.3 |
| 5 | 355.1 | 350.605 | 30/30→20/20→15/15 | 48/84 | 352.3 |
| 6 | 352.99 | 351.305 | 30/30→20/20→15/15 | 48/84 | 352.3 |
| 7 | 355.86 | 353.73 | 30/30→20/20 | 48/84 | 352.3 |
| 8 | 356.56 | 354.449 | 30/30 | 48/84 | 352.3 |
| 9 | 353.06 | 351.31 | 30/30→20/20→15/15 | 48/84 | 352.3 |

For example, Table 2 is a data table of the sizes of the first protective layers of N kinds of functional substrates in the second direction provided by an embodiment of the disclosure. For example, as shown in Table 2, taking 9 kinds of functional substrates of notebook computers with a size and specification of 15.6 inches as an example, the sizes Dᵢ of the first protective layers of the 9 kinds of functional substrates in the second direction are 351.32 mm, 352.68 mm, 351.285 mm, 351.305 mm, 350.605 mm, 351.305 mm, 353.73 mm, 354.449 mm and 351.31 mm, respectively. The widths Wᵢ of wires of the 9 kinds of functional substrates are 30→20→15 microns, 30→20 microns, 30→20→15 microns, 30→20→15 microns, 30→20→15 microns, 30→20→15 microns, 30→20→15 microns, 30→20→15 microns, 30→20 microns, 30→20 microns, 30→20→15 microns, respectively. The minimum value of Wᵢ in the 9 kinds of functional substrates is 30→20→15 microns, while the size Dₘᵢₙ₁ of the first protective layer of the functional substrate with the minimum value of Wᵢ in the 9 kinds of functional substrates in the second direction is 351.32 mm, 351.285 mm, 351.305 mm, 350.605 mm, 350.305 mm and 351.31 mm, respectively. And the size Y of the first opening in the second direction is greater than Dₘᵢₙ₁, so Y can be 352.3 mm. That is, the size of the first opening of the mask plate shared by the 9 kinds of functional substrates in the second direction can be 352.3 mm. For example, the maximum size of the first protective layer in the eighth functional substrate in the second direction is 354.449mm, while the corresponding wire width is 30 microns. The maximum number of parallel wires in the functional substrate of 15.6 inches in the second direction is usually 2*48=96. If the wire width is reduced from 30 microns to 15 microns, the size of the first protective layer of the functional substrate in the second direction can be reduced to 354.449−96*0.030 (while the wire width is reduced, the interval width between wires can also be correspondingly reduced, so it is 0.015 times 2)=351.569, which is less than the size Y of the first opening in the second direction. Similarly, if the size of the first protective layer needed to be formed in a functional substrate with a relatively large value of Wᵢ among the N kinds of functional substrates is greater than the size of the first opening, the size of the first protective layer can be reduced by reducing the wire width. Therefore, the mask plate manufactured by the manufacturing method of the mask plate can meet the requirements of the 9 kinds of functional substrates.

In some examples, the minimum interval width between two adjacent wires is Sᵢ, and the forming the first opening on the mask plate further includes: determining the size Y of the first opening in the second direction according to a size Dₘᵢₙ₂ of the first protective layer in a functional substrate with a minimum value of Sᵢ among the N kinds of functional substrates in the second direction, where Y is greater than Dₘᵢₙ₂.

For example, as shown in Table 2, taking 9 kinds of functional substrates of notebook computers with a size and specification of 15.6 inches as an example, the sizes Dᵢ of the first protective layers of the 9 kinds of functional substrates in the second direction are 351.32 mm, 352.68 mm, 351.285 mm, 351.305 mm, 350.605 mm, 351.305 mm, 353.73 mm, 354.449 mm and 351.31 mm, respectively. The interval widths Si between two adjacent wires of the 9 kinds of functional substrates are 30→20→15 microns, 30→20 microns, 30→20→15 microns, 30→20→15 microns, 30→20→15 microns, 30→20→15 microns, 30→20→15 microns, 30→20 microns, 30 microns, 30→20→15 microns (in general, the interval width between two adjacent wires is the same as the wire width). The minimum value of Sᵢ in the 9 kinds of functional substrates is 30→20→15 microns, while the size Dₘᵢₙ₁ of the first protective layer of the functional substrate with the minimum value of Sᵢ in the 9 kinds of functional substrates in the second direction is 351.32 mm, 351.285 mm, 351.305 mm, 350.605 mm, 350.305 mm, 351.31 mm, respectively. And the size Y of the first opening in the second direction is greater than Dₘᵢₙ₁, so Y can be 352.3 mm. That is, the size of the first opening of the mask plate shared by the 9 kinds of functional substrates in the second direction can be 352.3 mm. For example, the maximum size of the first protective layer in the second direction in the eighth functional substrate is 354.449 mm, and the corresponding wire width is 30 microns. The maximum number of parallel wires in the functional substrate of 15.6 inches in the second direction is usually 2*48=96. If the wire width is reduced from 30 microns to 15 microns, the size of the first protective layer of the functional substrate in the second direction can be reduced to 354.449−96*0.030 (while the wire width is reduced, the interval width between wires can also be correspondingly reduced, so it is 0.015 times 2)=351.569, which is less than the size Y of the first opening in the second direction. Similarly, if the size of the first protective layer needed to be formed in a functional substrate with a relatively large value of Sᵢ among the N kinds of functional substrates is greater than the size of the first opening, the size of the first protective layer can be reduced by reducing the wire width. Therefore, the mask plate manufactured by the manufacturing method of the mask plate can meet the requirements of the 9 kinds of functional substrates.

It should be noted that, as shown in FIG. 2, because the number of wires 131 on both sides of the functional region 101 gradually increases from top to bottom, the 30→20→15 microns mentioned above refers to that the wire width or the interval width between two adjacent wires can be reduced from 30 microns to 20 microns, and then from 20 microns to 15 microns.

In some examples, the size Y of the first opening in the second direction is also greater than the size of the functional substrate in the second direction (outline) minus 0.32 mm*2, that is, the first opening is at least 0.32 mm inward in the second direction from the edge of the functional substrate in the second direction.

In some examples, as shown in FIG. 2, the size of the first protective layer in the second direction (i.e., the size of a region needed to be covered by the first protective layer in the second direction) can be the sum of the size of the functional region 101 in the second direction, the size of a region needed to be covered by the plurality of wires 131 on both sides of the functional region 101 in the second direction, the size of contact pads of the wires 131 and the touch electrodes in the functional region 101 in the second direction, and the size of a ground wire (not shown in the figure) in the second direction. It should be noted that the first protective layer can cover the ground wire to prevent the ground wire from being corroded, and the position of the ground wire can be set according to the actual product.

In some examples, the forming the first opening on the mask plate further includes:

determining the size Y of the first opening in the second direction according to a median Dₘ of Dᵢ in the N kinds of functional substrates, where Y is greater than Dₘ. Therefore, it can be ensured that the size Y of the first opening in the second direction is at least greater than the size of the first protective layer of N/2 kinds of functional substrates in the second direction, so that on the one hand, the mask plate manufactured by the manufacturing method of the mask plate can meet the requirements of the N kinds of functional substrates, and on the other hand, the change in the wire width or the interval width between two adjacent wires with respect to the N kinds of functional substrates can be reduced.

In some examples, the manufacturing method of the mask plate further includes: forming a fourth opening on the mask plate, wherein the fourth opening is configured to pattern an optical adhesive layer of the N kinds of functional substrates to form a block pattern 140 at a corner of the N kinds of functional substrates, and the block pattern 140 covers an alignment mark of the N kinds of functional substrates. As shown in FIG. 2, the functional substrate 100 includes a block pattern 140 located at a corner.

For example, the side length of the block pattern 140 is 2-4 times of the side length of the alignment mark.

In some examples, the base substrate can be a cover plate of a display panel, that is, the functional substrate can be integrated on the display panel. For example, the cover plate can be a glass cover plate.

For example, as shown in FIG. 2, the bonding region of the functional substrate adopts a non-pair Pin design, that is, all wires are connected to the bonding region 102 from the side of the bonding region 102 close to the effective touch region 101. Of course, the embodiments of that present disclosure include but are not limited to this case.

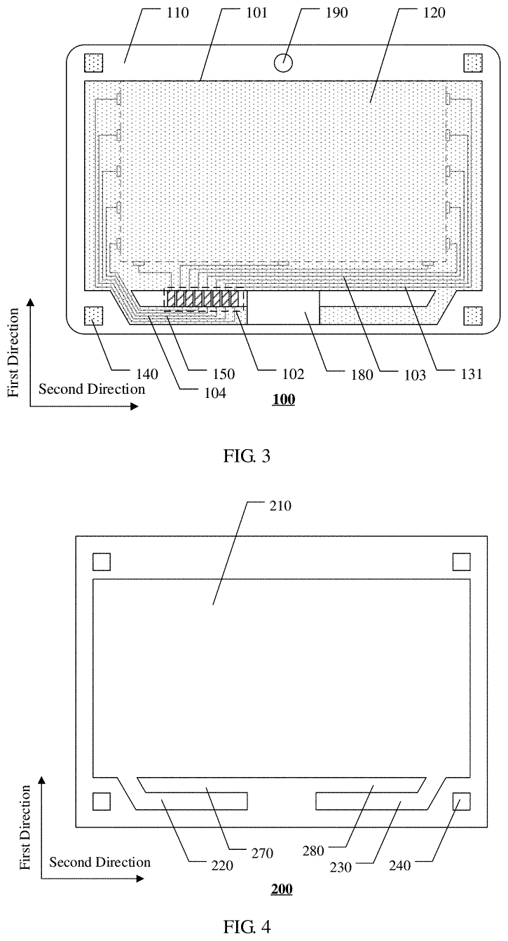

FIG. 3 is a schematic plan view of another functional substrate according to an embodiment of the present disclosure. As shown in FIG. 3, the functional substrate 100 includes a bonding region 102 located on one side of the first protective layer 120. The manufacturing method of the mask plate further includes: forming a second opening on the mask plate, wherein the second opening is configured to pattern an optical adhesive layer of the N kinds of functional substrates to form a second protective layer, and the second protective layer is located on one side of the bonding region away from the first protective layer and is connected to the first protective layer. For example, as shown in FIG. 3, the functional substrate 100 includes a second protective layer 150 located on the side of the bonding region 102 away from the first protective layer 120 and connected to the first protective layer 120. In this case, as shown in FIG. 3, the bonding region 102 of the functional substrate adopts a pair Pin design, part of the wires can be bypassed from one side of the bonding region 102 and be connected to the bonding region 102 on the side of the bonding region 102 away from the first protective layer 120, this part of the wires are arranged opposite to another part of the wires in the bonding region 102. The second protective layer 150 can cover this part of the wires, thereby reducing the length of the bonding region 102.

In some examples, as shown in FIGS. 2-3, the functional substrate further includes a trademark region 180 for setting a trademark therein. An orthographic projection of the second protective layer 150 on the base substrate 110 does not overlap with an orthographic projection of the trademark region 180 on the base substrate 110.

In some examples, the size of the second opening in the second direction is greater than the size of, half of the number of touch driving lines, and the number of touch sensing lines multiplied by 2 times of the wire width.

An embodiment of the present disclosure provides a manufacturing method of a mask plate, which includes: forming a first opening 210 on the mask plate, wherein the first opening 210 is configured to form a first protective layer 120 for covering a first region of a plurality of functional substrates 100, and the first region includes a functional region 101 and a first wiring region 103 at a periphery of the functional region 101; and forming a second opening 220 on the mask plate, wherein the second opening 220 is connected to the first opening 210, and is configured to form a second protective layer 150 for covering a second region of at least one of the plurality of functional substrates 100, and the second region includes a second wiring region 104. In this case, the mask plate includes a first shielding strip portion located between the first opening and the second opening, the first protective layer and the second protective layer are connected and belong to a same film layer, the first shielding strip portion is configured to form a first groove region of the film layer, the first groove region corresponds to a bonding region 102 of the plurality of functional substrates, and the second wiring region 104 is located on one side of the bonding region 102 away from the first circuit region 103.

In some examples, the manufacturing method of the mask plate further includes: forming a third opening on the mask plate, wherein the third opening is communicated with the first opening and is oppositely arranged at an interval with the second opening, and the mask plate includes a second shielding strip portion between the first opening and the third opening and configured to form a second groove region of the film layer. Therefore, the mask plate can be applied to more functional substrates. Thus, in the case where the plurality of functional substrates include a wiring region formed on the right side, the third opening can also be used to form a protective layer covering the wiring region of at least one of the plurality of functional substrates.

In some examples, the functional substrate further includes an aperture region 190 for setting a photosensitive device such as a camera.

An embodiment of the present disclosure provides a mask plate. FIG. 4 is a schematic plan view of a mask plate according to an embodiment of the present disclosure. As shown in FIG. 4, the mask plate 200 includes: a first opening 210, configured to form a first protective layer for covering a first region of a plurality of functional substrates, the first region including a functional region and a first wiring region at a periphery of the functional region; a second opening 220, connected to the first opening and configured to form a second protective layer for covering a second region of at least one of the plurality of functional substrates, the second region including a second wiring region; and a first shielding strip portion 270 between the first opening and the second opening, wherein the first protective layer and the second protective layer are connected and belong to a same film layer, the first shielding strip portion is configured to form a first groove region of the film layer, the first groove region corresponds to a bonding region of the plurality of functional substrates, and the second wiring region is on one side of the bonding region away from the first wiring region.

In some examples, as shown in FIG. 4, the mask plate 200 further includes: a third opening 230, communicated with the first opening 210, and oppositely arranged at an interval with the second opening 220. For example, the third opening 230 and the second opening 220 are symmetrically arranged with respect to a perpendicular bisector of the first opening 210 along the direction from the first opening 210 to the second opening 220. And the mask plate 200 further includes: a second shielding strip portion 280 located between the first opening 210 and the third opening 230 and configured to form a second groove region of the film layer.

In some examples, as shown in FIG. 4, the mask plate 200 further includes: a fourth opening 240, configured to form a block pattern 140 for covering a third region of the plurality of functional substrates, wherein the third region includes an alignment marks, and the block pattern 140 and the first protective layer belong to the same film layer.

In some examples, as shown in FIG. 4, the fourth opening 240 is used to form the block pattern 140, and the second opening 220 can be used to form the second protective layer 220. The positions and sizes of the second opening 220 and the fourth opening 240 can be referred to the above-mentioned embodiments of the manufacturing method of the mask plate, and will not be described here again.

For example, the fourth opening 240 is used to pattern an optical adhesive layer of the functional substrate to form a block pattern located at a corner of the functional substrate, and the block pattern covers the alignment mark of the N kinds of functional substrates.

In the above embodiments, the first opening 210 can be used to pattern an optical adhesive layer of the functional substrate to form a first protective layer for covering the functional region of the functional substrate. The functional substrate further includes a base substrate and a plurality of wires, an orthographic projection of the plurality of wires on the base substrate falls within an orthographic projection of the first protective layer on the base substrate. The size of the first protective layer in each kind of N kinds of functional substrates in a first direction is Li, and the width of each of the plurality of wires in each kind of the N kinds of functional substrates is Wᵢ; the size X of the first opening in the first direction is greater than a size Lₘᵢₙ₁ of the first protective layer in a functional substrate with a minimum value of Wᵢ among the N kinds of functional substrates in the first direction. The functional substrate further includes a bonding region, the first direction is perpendicular to a direction from the functional region to the bonding region, N is a positive integer greater than or equal to 3, and i is a positive integer greater than or equal to 1 and less than or equal to N.

The mask plate provided by the embodiment of the disclosure can be used for products of different styles, so that the mask plate for forming the first protective layer does not need to be redesigned each time opening a new product, and the opening cost can be effectively reduced.

In some examples, as shown in FIG. 4, an interval width between two adjacent wires is Sᵢ, and the size X of the first opening 210 in the first direction is greater than a size Lₘᵢₙ₂ of the first protective layer in a functional substrate with a minimum value of Sᵢ among the N kinds of functional substrates in the first direction.

In some examples, as shown in FIG. 4, the size X of the first opening 210 in the first direction is greater than a median Lₘ of Lᵢ in the N kinds of functional substrates. Therefore, it can be ensured that the size X of the first opening in the first direction is at least greater than the size of the first protective layer of N/2 kinds of functional substrates in the first direction, so that on the one hand, the mask plate manufactured by the manufacturing method of the mask plate can meet the requirements of the N kinds of functional substrates, and on the other hand, the change in the wire width or the interval width between two adjacent wires with respect to the N kinds of functional substrates can be reduced.

In some examples, a size of the first protective layer in each kind of the N kinds of functional substrates in a second direction is Dᵢ, a size Y of the first opening in the second direction is greater than a size Dₘᵢₙ₁ of the first protective layer in the functional substrate with the minimum value of Wᵢ among the N kinds of functional substrates in the second direction, and the second direction is perpendicular to the first direction.

In some examples, the interval width between two adjacent wires is Sᵢ, and the size Y of the first opening in the second direction is greater than a size Dₘᵢₙ₂ of the first protective layer in a functional substrate with a minimum value of Sᵢ among the N kinds of functional substrates in the second direction.

In some examples, the size Y of the first opening in the second direction is greater than a median Dₘ of Dᵢ in the N kinds of functional substrates.

It should be noted that specific examples of the size of the first opening in the second direction described above can be referred to the relevant description in Table 2, and will not be described here again.

In some examples, the wires include touch sensing lines and touch driving lines.

In some examples, the base substrate includes a cover plate of a display panel.

In some examples, as shown in FIG. 4, the shape of the first opening 120 includes a rectangle.

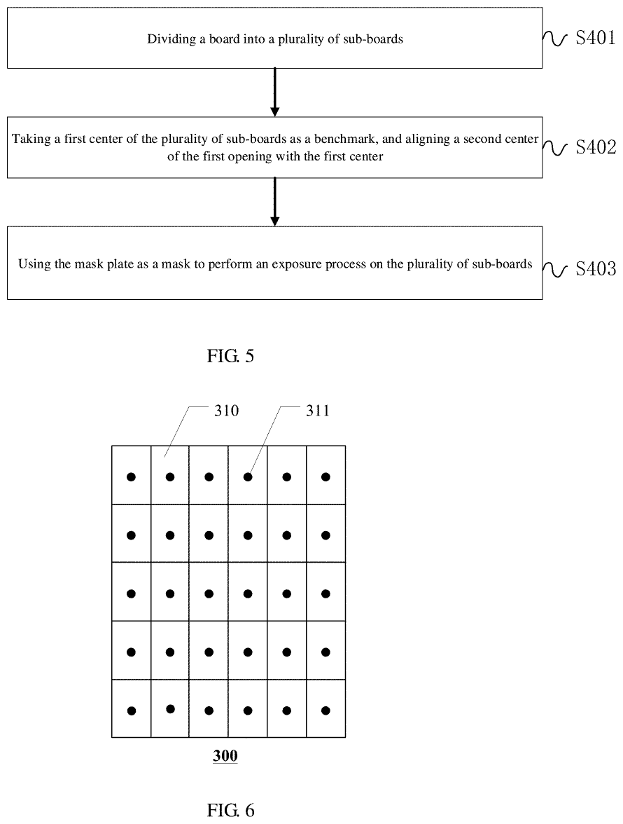

An embodiment of the present disclosure provides a patterning method using the mask plate described above. FIG. 5 is a schematic diagram of a patterning method using a mask plate according to an embodiment of the present disclosure. As shown in FIG. 5, the patterning method using the mask plate can pattern an optical adhesive layer of N kinds of functional substrates. The patterning method of using the mask plate includes the following steps S401-S403.

Step S401: dividing a board into a plurality of sub-boards.

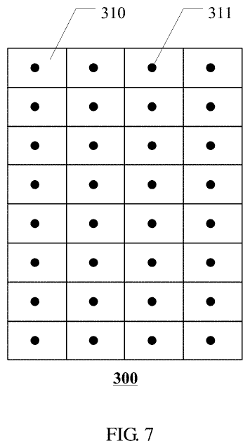

For example, taking a functional substrate of a notebook computer of 15.6 inches as an example, FIG. 6 is a schematic diagram of a board divided into 30 sub-boards according to an embodiment of the present disclosure, and FIG. 7 is a schematic diagram of a board divided into 32 sub-boards according to an embodiment of the present disclosure. As shown in FIG. 6 and FIG. 7, a large board 300 can be divided into 30 or 32 sub-boards 310, each sub-board is used to form a functional substrate of a notebook computer of 15.6 inches.

Step S402: taking a first center 311 of the plurality of sub-boards 310 as a benchmark, and aligning a second center of the first opening with the first center.

Step S403: using the mask plate as a mask to perform an exposure process on the plurality of sub-boards.

The patterning method using the mask plate provided by the embodiments of the present disclosure takes the first center of the sub-board as a benchmark and aligns the second center of the first opening with the first center, so that N kinds of functional substrates can share the mask plate, that is, when the mask plate is used for patterning an optical adhesive of N kinds of functional substrates, the optical adhesive pattern obtained by the patterning process can meet the requirements of the N kinds of functional substrates. An embodiment of the present disclosure further provides a manufacturing method of N kinds of display panels. Each kind of the N kind of functional substrates includes a first protective layer, a bas substrate and a plurality of wires, the first protective layer covers at least a functional region of the functional substrate, and an orthographic projection of the plurality of wires on the base substrate falls within an orthographic projection of the first protective layer on the base substrate. The manufacturing method includes: determining a size Lᵢ of the first protective layer in each kind of N kinds of functional substrates in a first direction; determining a width Wᵢ of each of the plurality of wires in each kind of the N kinds of functional substrates; determining a size X of the first opening in the first direction according to a size L_{min 1} of the first protective layer in a functional substrate with a minimum value of Wᵢ among the N kinds of functional substrates in the first direction, where X is greater than Lₘᵢₙ₁, N is a positive integer greater than or equal to 3, and i is a positive integer greater than or equal to 1 and less than or equal to N; and patterning an optical adhesive layer of the N kinds of functional substrates by using the first opening of the mask plate to form a first protective layer. It should be noted that if the size of the first protective layer needed to be formed in a functional substrate with a relatively large value of Wᵢ among the N kinds of functional substrates is greater than the size of the first opening, the size of the first protective layer can be reduced by reducing the width of the wire, so that the mask plate provided by the present embodiment can meet the requirements of the N kinds of functional substrates. In addition, the above N kinds of functional substrates belong to functional substrates with the same size and specification.

The manufacturing method of the N kinds of display panels provided by the embodiments of the present disclosure can reduce the number of mask plates, thereby reducing the manufacturing cost. And therefore, the mask plate for forming the first protective layer does not need to be redesigned each time opening a new product, thereby effectively reducing the opening cost.

In some examples, an interval width between two adjacent wires is Sᵢ, and the size X of the first opening in the first direction is greater than a size Lₘᵢₙ₂ of the first protective layer in a functional substrate with a minimum value of Sᵢ among the N kinds of functional substrates in the first direction. For more details, the related description of the embodiments of the manufacturing method of the mask plate can be referred to.

In some examples, the size X of the first opening 210 in the first direction is greater than a median Lm of Lᵢ in the N kinds of functional substrates. Therefore, it can be ensured that the size X of the first opening in the first direction is at least greater than the size of the first protective layer of N/2 kinds of functional substrates in the first direction, so that on the one hand, the manufacturing method can meet the requirements of the N kinds of functional substrates, and on the other hand, the change in the wire width or the interval width between two adjacent wires with respect to the N kinds of functional substrates can be reduced.

In some examples, the manufacturing method further includes: determining a size Dᵢ of the first protective layer in each kind of the N kinds of functional substrates in a second direction; determining a width Wᵢ of each of the plurality of wires in each kind of the N kinds of functional substrates; and determining a size Y of the first opening in the second direction according to a size Dₘᵢₙ₁ of the first protective layer in the functional substrate with the minimum value of Wᵢ among the N kinds of functional substrates in the second direction, wherein the wires extend along the first direction, and Y is greater than Dₘᵢₙ₁. Similarly, if the size of the first protective layer needed to be formed in a functional substrate with a relatively large value of Wᵢ among the N kinds of functional substrates is greater than the size of the first opening, the size of the first protective layer can be reduced by reducing the width of the wire. Therefore, the mask plate manufactured by the manufacturing method of the mask plate can meet the requirements of the N kinds of functional substrates. For more details, the related description of the embodiments of the manufacturing method of the mask plate can be referred to.

In some examples, the minimum interval width between two adjacent wires is Sᵢ, and the manufacturing method further includes: determining the size Y of the first opening in the second direction according to a size Dₘᵢₙ₂ of the first protective layer in a functional substrate with a minimum value of Sᵢ among the N kinds of functional substrates in the second direction, where Y is greater than Dₘᵢₙ₂. Similarly, if the size of the first protective layer needed to be formed in a functional substrate with a relatively large value of Sᵢ among the N kinds of functional substrates is greater than the size of the first opening, the size of the first protective layer can be reduced by reducing the width of the wire. Therefore, the mask plate manufactured by the manufacturing method of the mask plate can meet the requirements of the N kinds of functional substrates. For more details, the related description of the embodiments of the manufacturing method of the mask plate can be referred to.

In some examples, the size Y of the first opening in the second direction is also greater than the size of the functional substrate in the second direction (outline) minus 0.32 mm*2, that is, the first opening is at least 0.32 mm inward in the second direction from the edge of the functional substrate in the second direction. For more details, the related description of the embodiments of the manufacturing method of the mask plate can be referred to.

In some examples, the manufacturing method further includes: determining the size Y of the first opening in the second direction according to a median Dₘ of Dᵢ in the N kinds of functional substrates, where Y is greater than Dₘ. Therefore, it can be ensured that the size Y of the first opening in the second direction is at least greater than the size of the first protective layer of N/2 kinds of functional substrates in the second direction, so that on the one hand, the mask plate manufactured by the manufacturing method of the mask plate can meet the requirements of the N kinds of functional substrates, and on the other hand, the change in the wire width or the interval width between two adjacent wires with respect to the N kinds of functional substrates can be reduced. For more details, the related description of the embodiments of the manufacturing method of the mask plate can be referred to.

In some examples, the shape of the first opening 120 includes a rectangle.

In some examples, each kind of the N kinds of functional substrates further includes a block pattern located at a corner, and the manufacturing method further includes: patterning an optical adhesive layer of the N kinds of functional substrates by using a second opening of the mask plate to form a block pattern. The block pattern covers an alignment mark of the N kinds of functional substrates.

For example, the side length of the block pattern is 2-4 times the side length of the alignment mark.

In some examples, each kind of the N kinds of functional substrates includes a bonding region located on one side of the first protective layer, and the manufacturing method further includes: patterning an optical adhesive layer of the N kinds of functional substrates using a third opening of the mask plate to form a second protective layer, wherein the second protective layer is located on one side of the bonding region away from the first protective layer and is connected to the first protective layer. The bonding region of the functional substrate manufactured by the manufacturing method adopts a pair Pin design, part of the wires can be bypassed from one side of the bonding region and be connected to the bonding region on the side of the bonding region away from the first protective layer, this part of the wires are arranged opposite to another part of the wires in the bonding region. The second protective layer can cover this part of the wires, thereby reducing the length of the bonding region.

In some examples, each kind of the N kinds of functional substrates further includes a trademark region for setting a trademark therein. An orthographic projection of the second protective layer on the base substrate does not overlap with an orthographic projection of the trademark region on the base substrate.

In some examples, the size of the second opening in the second direction is greater than the size of, half of the number of touch driving lines, and the number of touch sensing lines multiplied by 2 times of the wire width.

The following statements should be noted.

(1) The accompanying drawings involve only the structure(s) in connection with the embodiment(s) of the present disclosure, and other structure(s) can be referred to common design(s).

(2) In case of no conflict, the embodiments of the present disclosure and the features in the embodiments can be combined with each other.

What have been described above are only specific implementations of the present disclosure, the protection scope of the present disclosure is not limited thereto. Any changes or substitutions easily occur to those skilled in the art within the technical scope of the present disclosure should be covered in the protection scope of the present disclosure. Therefore, the protection scope of the present disclosure should be based on the protection scope of the claims.

What is claimed is:

1. A mask plate, comprising:
a first opening, configured to form a first protective layer for covering a first region of a plurality of functional substrates, the first region comprising a functional region and a first wiring region at a periphery of the functional region;
a second opening, connected to the first opening and configured to form a second protective layer for covering a second region of at least one of the plurality of functional substrates, the second region comprising a second wiring region; and
a first shielding strip portion, between the first opening and the second opening,
wherein the first protective layer and the second protective layer are connected and belong to a same film layer, the first shielding strip portion is configured to form a first groove region of the film layer, the first groove region corresponds to a bonding region of the plurality of functional substrates, and the second wiring region is on one side of the bonding region away from the first wiring region.

2. The mask plate according to claim 1, further comprising:
a third opening, communicated with the first opening, and oppositely arranged at an interval with the second opening; and
a second shielding strip portion, between the first opening and the third opening, and configured to form a second groove region of the film layer.

3. The mask plate according to claim 1, further comprising: a fourth opening, configured to form a block pattern for covering a third region of the plurality of functional substrates, the third region comprising an alignment mark,
wherein the block pattern and the first protective layer belong to the same film layer.

4. The mask plate according to claim 1, wherein each of the plurality of functional substrates comprises a base substrate and a plurality of wires, an orthographic projection of the plurality of wires on the base substrate falls within an orthographic projection of the first protective layer on the base substrate,
a size of the first protective layer in each kind of N kinds of functional substrates in a first direction is Lᵢ, and a width of each of the plurality of wires in each kind of the N kinds of functional substrates is Wᵢ;
a size X of the first opening in the first direction is greater than a size Lₘᵢₙ₁ of the first protective layer in a functional substrate with a minimum value of Wᵢ among the N kinds of functional substrates in the first direction, and the functional substrate further comprises a bonding region, the first direction is perpendicular to a direction from the functional region to the bonding region,
N is a positive integer greater than or equal to 3, and i is a positive integer greater than or equal to 1 and less than or equal to N.

5. The mask plate according to claim 4, wherein an interval width between two adjacent wires is Sᵢ, and the size X of the first opening in the first direction is greater than a size Lₘᵢₙ₂ of the first protective layer in a functional substrate with a minimum value of Sᵢ among the N kinds of functional substrates in the first direction.

6. The mask plate according to claim 5, wherein the size X of the first opening in the first direction is greater than a median Lₘ of Lᵢ in the N kinds of functional substrates.

7. The mask plate according to claim 5, wherein a size of the first protective layer in each kind of the N kinds of functional substrates in a second direction is Dᵢ, a size Y of the first opening in the second direction is greater than a size Dₘᵢₙ₁ of the first protective layer in the functional substrate with the minimum value of Wᵢ among the N kinds of functional substrates in the second direction, and
the second direction is perpendicular to the first direction.

8. The mask plate according to claim 7, wherein the interval width between two adjacent wires is Sᵢ, and the size Y of the first opening in the second direction is greater than a size Dₘᵢₙ₂ of the first protective layer in a functional substrate with a minimum value of Sᵢ among the N kinds of functional substrates in the second direction.

9. The mask plate according to claim 7, wherein the size Y of the first opening in the second direction is greater than a median Dₘ of Dᵢ in the N kinds of functional substrates.

10. A patterning method using the mask plate according to claim 1, comprising:
patterning an optical adhesive layer of N kinds of functional substrates using the mask plate.

11. The patterning method according to claim 10, further comprising:
dividing a board into a plurality of sub-boards;
taking a first center of the plurality of sub-boards as a benchmark, and aligning a second center of the first opening with the first center; and
using the mask plate as a mask to perform an exposure process on the plurality of sub-boards.

12. A manufacturing method of a mask plate, comprising:
forming a first opening on the mask plate, wherein the first opening is configured to form a first protective layer for covering a first region of a plurality of functional substrates, and the first region comprises a functional region and a first wiring region at a periphery of the functional region; and
forming a second opening on the mask plate, wherein the second opening is connected to the first opening and is configured to form a second protective layer for covering a second region of at least one of the plurality of functional substrates, and the second region comprises a second wiring region,
wherein the mask plate comprises a first shielding strip portion between the first opening and the second opening, the first protective layer and the second protective layer are connected and belong to a same film layer, the first shielding strip portion is configured to form a first groove region of the film layer, the first groove region corresponds to a bonding region of the plurality of functional substrates, and the second wiring region is on one side of the bonding region away from the first wiring region.

13. The manufacturing method of the mask plate according to claim 12, further comprising:
forming a third opening on the mask plate, wherein the third opening is communicated with the first opening and is oppositely arranged at an interval with the second opening, and
the mask plate comprises a second shielding strip portion between the first opening and the third opening and configured to form a second groove region of the film layer.

14. The manufacturing method of the mask plate according to claim 12, further comprising:
forming a fourth opening on the mask plate, wherein the fourth opening is configured to form a block pattern for covering a third region of the plurality of functional substrates, the third region comprises an alignment mark, and
the block pattern and the first protective layer belong to the same film layer.

15. The manufacturing method of the mask plate according to claim 12, wherein each of the plurality of functional substrates comprises a base substrate and a plurality of wires, an orthographic projection of the plurality of wires on the base substrate falls within an orthographic projection of the first protective layer on the base substrate, and the forming the first opening on the mask plate comprises:
determining a size Lᵢ of the first protective layer in each kind of N kinds of functional substrates in a first direction;
determining a width Wᵢ of each of the plurality of wires in each kind of the N kinds of functional substrates; and
determining a size X of the first opening in the first direction according to a size Lₘᵢₙ₁ of the first protective layer in a functional substrate with a minimum value of Wᵢ among the N kinds of functional substrates in the first direction, wherein the functional substrate further comprises a bonding region, the first direction is perpendicular to a direction from the functional region to the bonding region,
N is a positive integer greater than or equal to 3, and i is a positive integer greater than or equal to 1 and less than or equal to N.

16. The manufacturing method of the mask plate according to claim 15, wherein an interval width between two adjacent wires is Sᵢ, and the forming the first opening on the mask plate further comprises:
determining the size X of the first opening in the first direction according to a size Lₘᵢₙ₂ of the first protective layer in a functional substrate with a minimum value of Sᵢ among the N kinds of functional substrates in the first direction,
where X is greater than Lₘᵢₙ₂.

17. The manufacturing method of the mask plate according to claim 15, wherein the forming the first opening on the mask plate further comprises:
determining the size X of the first opening in the first direction according to a median Lₘ of Lᵢ in the N kinds of functional substrates,
where X is greater than Lₘ.

18. The manufacturing method of the mask plate according to claim 15, wherein the forming the first opening on the mask plate further comprises:
determining a size Dᵢ of the first protective layer in each kind of the N kinds of functional substrates in a second direction; and
determining a size Y of the first opening in the second direction according to a size Dₘᵢₙ₁ of the first protective layer in the functional substrate with the minimum value of Wᵢ among the N kinds of functional substrates in the second direction,
wherein the second direction is perpendicular to the first direction, and Y is greater than Dₘᵢₙ₁.

19. The manufacturing method of the mask plate according to claim 18, wherein the interval width between two adjacent wires is Sᵢ, and the forming the first opening on the mask plate further comprises:
determining the size Y of the first opening in the second direction according to a size Dₘᵢₙ₂ of the first protective layer in a functional substrate with a minimum value of Sᵢ among the N kinds of functional substrates in the second direction,
where Y is greater than Dₘᵢₙ₂.

20. The manufacturing method of the mask plate according to claim 18, wherein the forming the first opening on the mask plate further comprises:
determining the size Y of the first opening in the second direction according to a median Dₘ of Dᵢ in the N kinds of functional substrates,
where Y is greater than Dₘ.
